(19) United States
(12) Patent Application Publication
(10) Pub. No.: US 2002/0111046 A1
(43) Pub. Date: Aug. 15, 2002

(54) Semiconductor device fabricating method

(75) Inventors: Joo-Han Park, Suwon-city (KR); Sung-Hoan Kim, Suwon-city (KR); Myoung-Soo Kim, Suwon-city (KR); Seong-Ho Kim, Yongin-city (KR)

Correspondence Address: Anthony P. Onello, Jr., MILLS & ONELLO LLP, Suite 605, Eleven Beacon Street, Boston, MA, 02108, US

(73) Assignee: Samsung Electronics Co., Ltd.

(21) Appl. No.: 09/941,303

(22) Filed: Aug. 29, 2001

(30) Foreign Application Priority Data
Feb. 12, 2001 (KR) 01-6679

(51) Int. Cl. H01L 21/00; H01L 21/84; H01L 21/76

(52) U.S. Cl. 438/981; 438/424; 438/153

(57) ABSTRACT

A shallow trench isolation (STI) structure is constructed in dual gate oxide device that requires a high voltage and low-voltage operation, for example in a LCD driver IC. The disclosed fabrication method prevents deterioration in operational characteristics of resulting transistors and prevents decrease in the reliability of the gate oxide film. The method includes the steps of: preparing a semiconductor substrate having a first active region and a second active region that are isolated by an STI structure; forming a buffer oxide film in the first and second active regions on the substrate; forming a nitride film on the buffer oxide film and the STI region; forming a CVD oxide film on the nitride film; forming a photo-resist pattern on the CVD oxide film to mask a portion of the STI of an adjacent portion including the first active region; etching the CVD oxide film of the second active region side by using the photo-resist pattern as a mask to thereafter remove the photo-resist pattern; exposing the surface of the second active region by etching the nitride film and the buffer oxide film with the etched CVD oxide film as a mask; forming the first thermal oxide film for a gate oxide film on the exposed surface of the second active region; exposing the surface of the first active region by etching the residual CVD oxide film, the nitride film and the buffer oxide film, which remain in the first active region; and forming a second thermal oxide film for a gate oxide film, which has a thickness less than that of the first thermal oxide film, on the exposed surface of the first active region.

### BACKGROUND OF THE INVENTION

1. Field of the Invention

The present invention relates to a semiconductor device fabricating method that serves to prevent deterioration of operational characteristics of fabricated transistors and deterioration of the reliability of a gate oxide film, even in the case where a process of forming a dual gate oxide film is applied to a shallow trench isolation (STI) structure.

2. Description of the Related Art

Since power devices such as a liquid crystal display (LCD) driver IC (LDI) require both low voltage (LV) operation for driving an associated logic circuit, together with high voltage (HV) operation for driving the LCD during operation, associated gate oxide films are formed of a dual gate type. Also, the continuous trend toward ever-miniaturized line width requires the use of a trench isolation process (TI).

However, if the process for fabricating the dual gate oxide film is conducted in the same manner as it is applied to the STI structure that is formed as a result of TI process without any modification thereto, excessive numbers of STI recesses in the LV region are created during formation of the dual gate oxide film for the HV region, resulting in compromise of the overall device characteristics.

The source of the recesses lies in that since a CVD oxide film such as USG or HDP is used as a gap fill in the STI structure, and since a thermal oxide film is used as a gate oxide film, a severe dent is created in the boundary between the active region and the field region due to the difference in wet etch rate between the thermal oxide film and CVD oxide film.

This conventional process is explained in greater detail with reference to FIGS. 1a through 1c, which illustrate the process of fabricating the conventional dual gate oxide film.

For convenience' sake, the process is explained by being classified into 3 steps as follows.

In the drawings, reference symbol “I” indicates a first active region in which a thin gate oxide film for LV is formed and reference “II” indicates a second active region in which a thick gate oxide film for HV is formed.

First step:

As shown in FIG. 1a, the silicone substrate 10 is selectively etched to a predetermined thickness using a photo-resist pattern as a mask to define the field region so that trench (t) is formed. A CVD oxide film of USG or HDP material is then formed on the resultant structure so that the trench (t) is sufficiently filled. Next, it is chemically-mechanically polished so that the surface of the substrate 10 in the first and second active regions I, II is exposed to thereby form the STI 12 that is buried within the inside of the trench (t). The first thermal oxide film 14 for HV is subsequently formed to a thickness of 300A in the active regions I, II on the substrate 10.

Second step:

As shown in FIG. 1b, the resultant structure is patterned by a photo-resist film 16 so that the first active region I and the surrounding STI 12 may be partially exposed. The first thermal oxide film 14 is wet etched using the pattern as a mask and selectively remains exclusively in the HV region II.

Third step:

As shown in FIG. 1c, the photo-resist pattern 16 is removed and the second thermal oxide film 18 for LV is formed to a thickness of 40A in the first active region I. Thereby, the process for the dual gate oxide film is completed. Here, when the second thermal oxide film 18 is formed, the first thermal oxide film 14 also grows. However, since the amount of the growth is negligible, the result does not have a considerable effect on performance.

As a result, the first active region I is formed therein with a gate oxide film comprising the second thermal oxide film 18 material, having a relatively thin thickness of 40 Å, and the second active region II is formed therein with a gate oxide film comprising the first thermal oxide film 14 material, having a relatively thick thickness of 300 Å.

However, when the dual gate oxide film is formed in the STI structure in such a fabrication sequence, this process introduces a number of limitations.

In order to selectively leave the first thermal film 14 at a thickness of 300 Å, when the first thermal oxide film 14 of LV region I is removed by using the photo-resist pattern 16 as a mask, the STI 12, which is indicated by \mathring{a} in FIG. 1b, surrounding the perimeter of the LV region is recessed together with the first thermal oxide film 14. Accordingly, a dent occurs in the region, the boundary between the active region and the field region.

This dent phenomenon is caused by the difference in a wet etch rate between the first thermal oxide film 14 being used as a gate oxide film and the CVD oxide film forming the STI 12. For example, in the case that the STI 12 is filled with a HDP material, the depth of recess is approximately 200 Å relative to the substrate 10 of the active region. In contrast, in the case that the STI 12 is filled with a USG material, the recess amounts to approximately 1,000 Å relative to the substrate 10 of the active region; in this case, the dent is more severe.

FIG. 2 is a cross sectional view showing the device structure in which a dent has occurred in the \mathring{a} region shown in FIG. 1b. When the dent is created, poly residue remains in the region that is recessed during the gate poly etching as a follow up process, or the gate poly surrounds the field region and the active region at their boundary. Such a phenomenon results in deterioration of the gate oxide film due to the concentration of electric field created upward and sideward as well as deterioration in device characteristics such as a drop in the threshold voltage Vth of the transistor during device operation, an increase in threshold voltage leakage, and a decrease in punching margin.

In addition, the so-called “hump phenomenon” causes the transistor to operate as though it has two Vth values. According to the hump phenomenon, when the transistor is in operation, an “edge” channel (the channel of edge transistor) is first formed at the boundary between the active region and the field region thereby the transistor is turned on, and a “flat” channel (the channel of flat transistor) is formed at the center of the active region thereby the transistor is turned on.

In this manner, with increased integration, the TI technique is no longer suitable in realizing LDI processes.

### SUMMARY OF THE INVENTION

Accordingly, it is an object of the present invention to provide a method of fabricating a semiconductor device by which a dual gate oxide film can be formed by adding a CVD oxide film deposition process and a thin nitride film deposition process, even without the process of removing a thick thermal oxide film in a LV region. Thereby, dents can be prevented at the boundary of the active region and field region when the dual gate oxide film process is applied to a normal STI structure, thereby preventing decrease in operational characteristics of fabricated transistors, which otherwise would be caused in the conventional approaches through a concentration of electric field and hump phenomenon and deterioration in the gate oxide film.

In order to achieve the object, the semiconductor device fabricating method according to the present invention comprises the steps of: providing a semiconductor substrate having a first active region and a second active region that are isolated by to shallow trench isolation (STI) region; forming a buffer oxide film on the substrate in the first and second active regions; forming a nitride film on the buffer oxide film in the first and second active regions and the STI region; forming a CVD oxide film on the nitride film; forming a photo-resist pattern on the CVD oxide film to mask a portion of the STI region and the adjacent first active region; etching the CVD oxide film of the second active region using the photo-resist pattern as a mask and thereafter removing the photo-resist pattern; exposing the surface of the second active region by etching the nitride film and the buffer oxide film using the etched CVD oxide film as a mask; forming a first thermal oxide film for a gate oxide film on the exposed surface of the second active region; exposing the surface of the first active region by etching the CVD oxide film, the nitride film and the buffer oxide film, which remain in the first active region; and forming a second thermal oxide film for a gate oxide film on the exposed surface of the first active region, the second thermal oxide film having a thickness that is less than that of the first thermal oxide film.

In a preferred embodiment, the STI region comprises USG or HDP material. The buffer oxide film, for example a thermal oxide film, is preferably formed at a thickness of 100 to 120 Å The nitride film is preferably formed at a thickness of 90 to 110 Å. The CVD oxide film is preferably formed at a thickness of 90 to 110 Å The CVD oxide film may comprise a medium temperature oxide film that is deposited at a temperature of 700 to 800° C.

The method as claimed in claim 1, wherein the CVD oxide film is preferably etched by a wet etching method. The nitride film is preferably etched by a wet etching method in which phosphoric acid is used as an etchant.

The first thermal oxide film is preferably formed at a thickness of 400 to 450 Å. The second thermal oxide film is preferably formed at a thickness of 30 to 50 Å.

After the first gate oxide film is formed, the photo-resist pattern may be additionally formed so that the first gate oxide film and a portion of the adjacent STI are masked. In this case, the first gate oxide film is formed to a thickness of 250 to 350 Å. After the CVD oxide film, nitride film, and buffer oxide film that remain in the first active region side are etched, the photo-resist pattern may be further removed.

The first active region may comprise a low-voltage (LV) region, and the second active region may comprise a high-voltage (HV) region.

Before the nitride film is formed, a poly-silicone film may be further formed on the buffer oxide film and the STI region. The poly-silicone film is preferably formed to a thickness of 90 to 110 Å. The poly-silicone film may be removed when the nitride film and the buffer oxide film are etched by utilizing the etched CVD oxide film as a mask. The CVD oxide film, the nitride film and the buffer oxide film that remain in the first active region side are then etched, and the poly-silicone film is removed.

Since the gate oxide film is fabricated in such a manner that the surface of the substrate in the second active region (HV region) is first exposed by utilizing a mask of the CVD oxide film that remains in the first active region I and then the relatively thick thermal oxide film is selectively formed on the exposed surface only, the dual gate oxide film can be formed without the need for removing the thick thermal oxide film in the LV region, thereby preventing the generation of dents at the boundary of the active region and the field region.

### BRIEF DESCRIPTION OF THE DRAWINGS

The foregoing and other objects, aspects and advantages will be better understood from the following detailed description of a preferred embodiment of the invention with reference to the drawings, in which:

FIG. 1a through 1c are cross-sectional sequential illustrations of a method of forming a dual gate oxide film according to the prior art;

FIG. 2 shows defects that occur as a result of the method of forming the dual gate oxide film shown in FIG. 1a through 1c; and

FIG. 3a through 3e are sequential illustrations of a method of forming a dual gate oxide film according to the present invention.

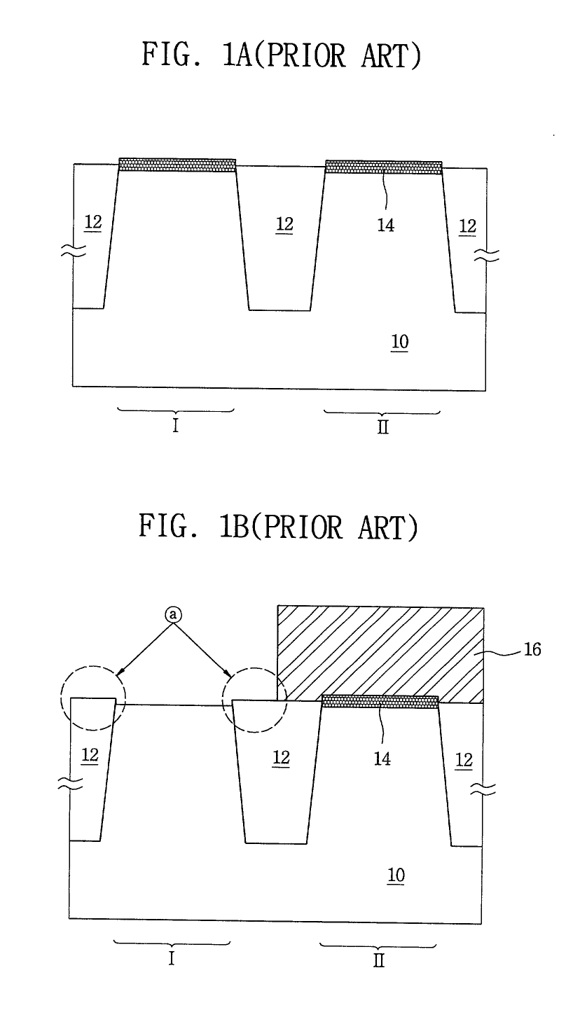

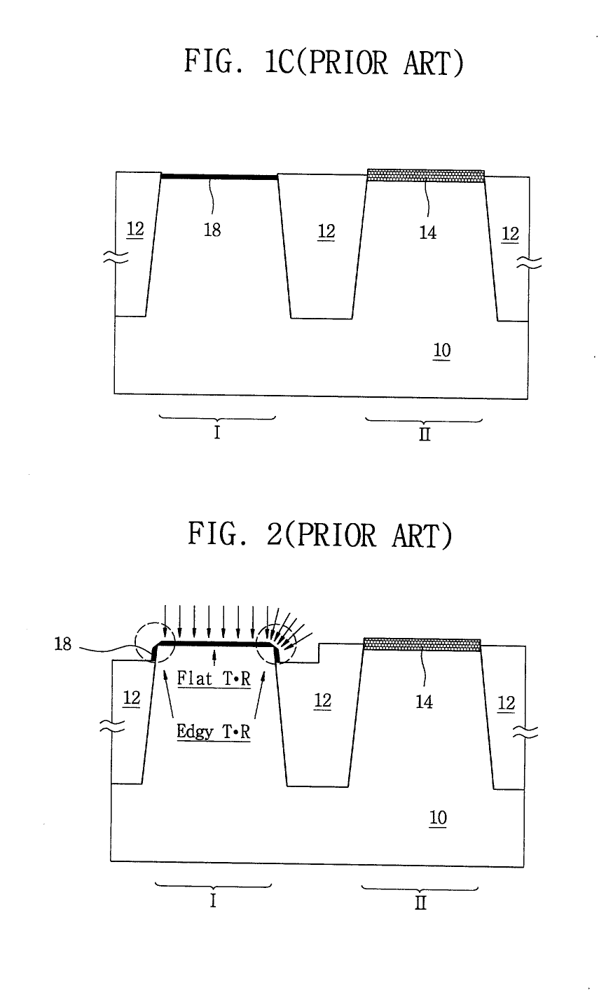

### DETAILED DESCRIPTION OF PREFERRED EMBODIMENTS

Hereinafter, the preferred embodiment of the present invention will be explained with reference to the accompanying drawings.

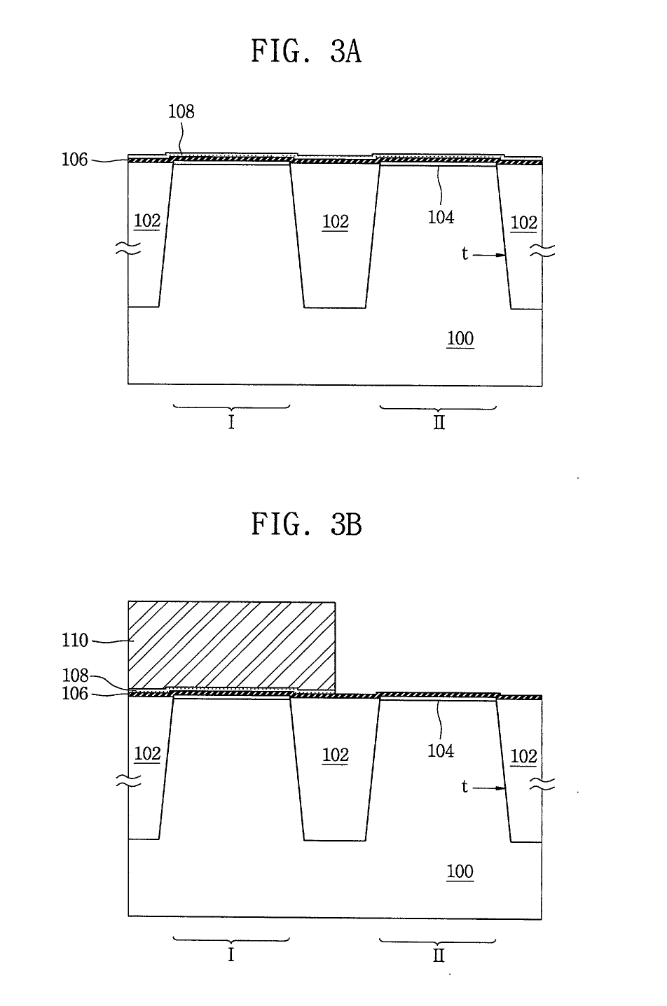

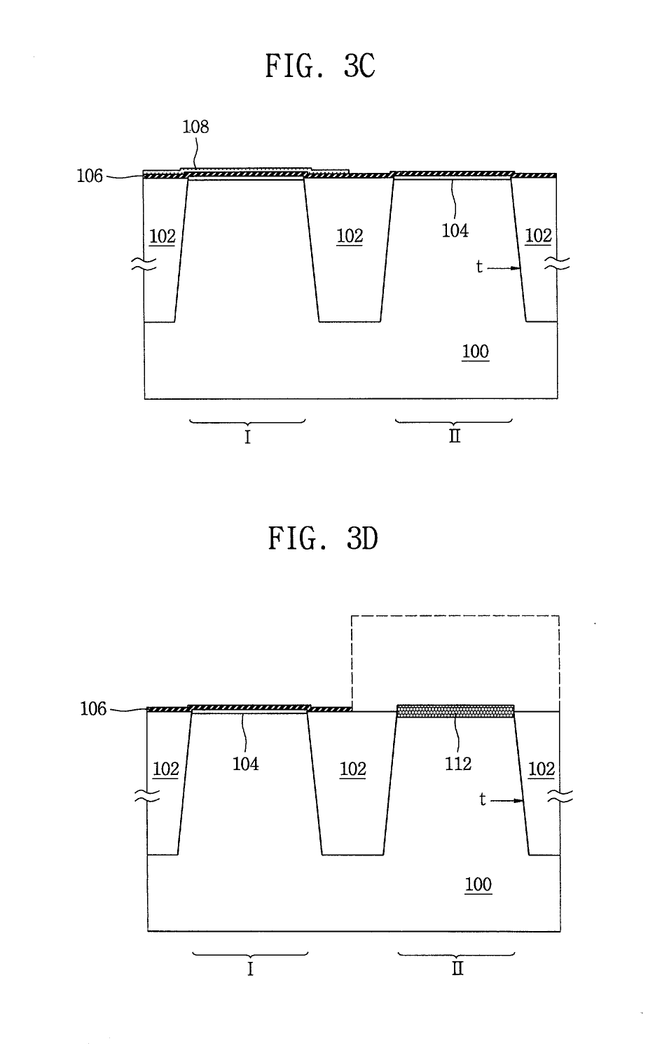

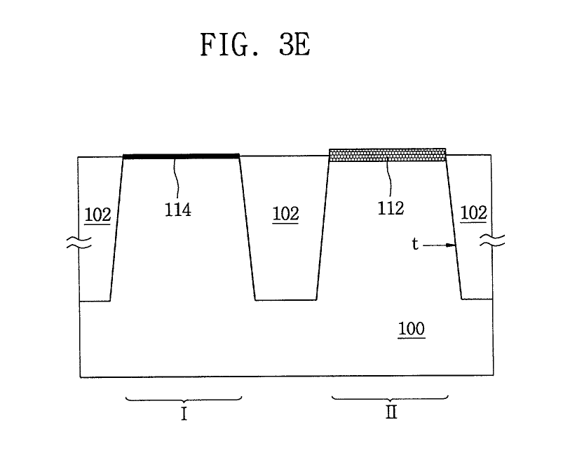

FIG. 3a through 3e are sequential cross-sectional views of a method of forming a dual gate oxide according to the present invention. The method comprises the following steps.

In the figures, reference symbol “I” indicates the first active region that is to be used as a LV region (in which a relatively thin gate oxide film is formed), and reference symbol “II” indicates the second active region that is to be used as a HV region (in which a relatively thick gate oxide film is formed).

As shown in FIG. 3a, a CVD oxide film, for example comprising USG or HDP material, is formed on a silicone substrate 100 that is provided with trench (t) so that the trench (t) is sufficiently filled. The CVD oxide film is then chemically mechanically polished so that the surface of the substrate 100 in the first and second active regions I, II is exposed, to thereby form the STI 102 that buries the inside of the trench (t). A buffer oxide film 104 of the thermal oxide film material is subsequently formed in the active regions I, II on the substrate 100 and a nitride film 106 is formed on the buffer oxide film 104 including the STI 102. Thereafter, a CVD oxide film 108 of medium temperature oxide (MTO) is formed on the resultant structure. Here, the MTO refers to an oxide film that is formed at a temperature of 700 to 800° C. The buffer oxide film 104 is formed, for example, to a thickness of 100 to 120 Å, the nitride film 106 is formed, for example, to a thickness of 90 to 110 Å, and the CVD oxide film 108 is formed, for example, to a thickness of 90 to 110 Å.

During the second step, as shown in FIG. 3b, the CVD oxide film 108 is patterned by a photo-resist pattern 110 so that the first active region I and the surrounding STI 102 may be partially masked. The second active region II and the adjacent CVD oxide film 108 are preferably wet etched, using the pattern 110 as a mask.

During the third step shown in FIG. 3c, the photo-resist pattern 110 is removed.

During the fourth step shown in FIG. 3d, the nitride film 106 and the buffer oxide film 104 are sequentially etched by utilizing as a mask the CVD oxide film 108 that remains in the first active region I, thereby exposing the surface of the second active region II. At this time, the nitride film 104 is etched by a wet etching method in which phosphoric acid is used as an etchant. The first thermal oxide film 112 is formed to a thickness of 400 to 450 Å on the exposed surface of the second active region II.

As the fifth step shown in FIG. 3e, the CVD oxide film 108, the nitride film 106 and the buffer oxide film 104 that remain in the first active region I and the adjacent STI 102 are sequentially etched, thereby exposing the surface of the first active region I.

At this time, the residual CVD oxide film 108 and the nitride film 106 are also etched by a wet etching method in which phosphoric acid is used as an etchant. Since a portion of the first oxide film 112 is also consumed during the etching process (particularly, etching of the buffer oxide film), only the first thermal oxide film 112 remains, for example at in a thickness of approximately 250 to 350 Å, on the second active region II when the etching process on the residual films are completed. The second thermal oxide film 114 is formed in a thickness of 30 to 50 Å, thinner than the thickness of the first thermal film 112 on the exposed surface of the first active region I. Therefore, the process for forming the dual gate oxide film is completed Again in this process, when the second thermal oxide film 114 is formed, the first thermal oxide film 112 of the second active region II grows an additional amount. However, since the amount of growth is minor, the resultant effect is negligible.

As a result, the first active region I is formed to include a gate oxide film of the second thermal film 114 material at a thickness of 30 to 50 Å, while the second active region II is formed to include a gate oxide film of the first thermal film 112 material at a thickness of 250 to 350 Å.

As described above, in the gate oxide film fabricating method of the present invention, after the nitride film 106 and the CVD oxide film 108 are sequentially deposited on the first and second active regions I, II, the surface of the substrate in the second active region (HV region) is first exposed by utilizing a mask of the CVD oxide 108 film that is patterned by the photolithography process (that is, the CVD oxide film remaining in the first active region I). Next, the relatively thick thermal oxide film 112 is selectively formed exclusively on the exposed surface. Accordingly, the dual gate oxide film can be formed, even without the need for removing the thick thermal oxide film in the LV region.

When the nitride film 106 and the buffer oxide film 104 are removed by utilizing as a mask the CVD oxide film 108 that remains in the first active region I (shown in FIG. 3d), and, subsequently, when the CVD oxide film 108, the nitride film 106 and the buffer oxide film 104 that remain in the first active region I are removed (shown in FIG. 3e), a portion of the STI 102 may become recessed.

However, since the resulting degree of recess is relatively minor, the process is not subject to the deep denting of conventional processes. The reason for this is that since the thickness of the buffer oxide film 104 is relatively thin, the resulting recess does not cause deep denting during the etching process.

As a result, denting can be prevented at the boundary of an active region and field region thereby preventing compromise of operational characteristics of fabricated transistors, which otherwise would have been caused by a concentration of electric field and hump phenomenon and deterioration in the gate oxide film according to the conventional process.

As another embodiment, following formation of the first thermal oxide film 112 to be used as a gate oxide in the second active region II, the first thermal oxide film 112 and the adjacent STI 102 are partly patterned by photo-resist. By using the patterned films as a mask, the CVD oxide film 108, nitride film 106 and buffer oxide film 104 are etched to remove them. This procedure prevents variations in uniformity of the first thermal oxide film 112 that may be caused during the etching process.

In this case, since the first thermal oxide film 112 is not consumed due to the photo-resist pattern when the CVD oxide film 108, the nitride film 106 and the buffer oxide film 104 that remain in the first active region I side are removed, and the first thermal oxide film 112 in the second active region II should grow to a thickness of 250 to 350 Å. The photo-resist pattern should then be removed following removal of the films that remain in the first active region I.

In another embodiment, after the buffer oxide film 104 of the thermal oxide film material is formed, a separate poly-silicone film is additionally formed to a thickness of 90 to 110 Å on the substrate including the buffer oxide film, and a nitride film 106 is formed on the resultant film.

In this case, when a thin gate oxide film and a thick gate oxide film coexist on an active region between adjacent STIs 102, the poly-silicone film operates as a buffering film, thereby minimizing the formation of a bird's beak at the boundary of the dual gate oxide film. In this procedure, during the process shown in FIG. 3d, the etching process should accommodate the removal of the poly-silicone film of the second active region II. During the step shown in FIG. 3e, the etching process should remove the poly-silicone film of the first active region I side.

While this invention has been particularly shown and described with references to preferred embodiments thereof, it will be understood by those skilled in the art that various changes in form and details may be made herein without departing from the spirit and scope of the invention as defined by the appended claims.

In the light of the foregoing, according to the present invention, the dual gate oxide film can be formed, without the need for removing the thick oxide film in the LV region, by adding the nitride film and the CVD oxide film deposition processes. Accordingly, dents do not occur at the boundary of the active region and the field region, thereby preventing deterioration in the gate oxide film and operational characteristics of a fabricated transistor, which would otherwise be caused by a concentration of electric field and existence of the hump phenomenon.

What is claimed is:

1. A method for fabricating a semiconductor device comprising:
providing a semiconductor substrate having a first active region and a second active region that are isolated by to shallow trench isolation (STI) region;
forming a buffer oxide film on the substrate in the first and second active regions;
forming a nitride film on the buffer oxide film in the first and second active regions and the STI region;
forming a CVD oxide film on the nitride film;
forming a photo-resist pattern on the CVD oxide film to mask a portion of the STI region and the adjacent first active region;
etching the CVD oxide film of the second active region using the photo-resist pattern as a mask and thereafter removing the photo-resist pattern;
exposing the surface of the second active region by etching the nitride film and the buffer oxide film using the etched CVD oxide film as a mask;
forming a first thermal oxide film for a gate oxide film on the exposed surface of the second active region;
exposing the surface of the first active region by etching the CVD oxide film, the nitride film and the buffer oxide film, which remain in the first active region; and
forming a second thermal oxide film for a gate oxide film on the exposed surface of the first active region, the second thermal oxide film having a thickness that is less than that of the first thermal oxide film

2. The method as claimed in claim 1, wherein the STI region comprises USG or HDP material.

3. The method as claimed in claim 1, wherein the buffer oxide film is formed at a thickness of 100 to 120 Å.

4. The method as claimed in claim 3, wherein the buffer oxide film is a thermal oxide film.

5. The method as claimed in claim 1, wherein the nitride film is formed at a thickness of 90 to 110 Å.

6. The method as claimed in claim 1, wherein the CVD oxide film is formed at a thickness of 90 to 110 Å.

7. The method as claimed in claim 6, wherein the CVD oxide film is a medium temperature oxide film that is deposited at a temperature of 700 to 800° C.

8. The method as claimed in claim 1, wherein the CVD oxide film is etched by a wet etching method.

9. The method as claimed in claim 1, wherein the nitride film is etched by a wet etching method in which phosphoric acid is used as an etchant.

10. The method as claimed in claim 1, wherein the first thermal oxide film is formed at a thickness of 400 to 450 Å.

11. The method as claimed in claim 1, wherein the second thermal oxide film is formed at a thickness of 30 to 50 Å.

12. The method as claimed in claim 1, wherein after the first gate oxide film is formed, the photo-resist pattern is additionally formed so that the first gate oxide film and a portion of the adjacent STI are masked.

13. The method as claimed in claim 12, wherein in the case where the photo-resist pattern is additionally formed, the first gate oxide film is formed to a thickness of 250 to 350 Å.

14. The method as claimed in claim 12, wherein in the case where the photo-resist pattern is additionally formed, after the CVD oxide film, nitride film, and buffer oxide film that remain in the first active region side are etched, the photo-resist pattern is further removed.

15. The method as claimed in claim 1, wherein the first active region is a low-voltage (LV) region, and the second active region is a high-voltage (HV) region.

16. The method as claimed in claim 1, wherein before the nitride film is formed, a poly-silicone film is further formed on the buffer oxide film and the STI region.

17. The method as claimed in claim 16, wherein the poly-silicone film is formed in a thickness of 90 to 110 Å.

18. The method as claimed in claim 16, wherein in the case where the poly-silicone film is further formed, the poly-silicone film is removed when the nitride film and the buffer oxide film are etched by utilizing the etched CVD oxide film as a mask.

19. The method as claimed in claim 16, wherein in the case where the poly-silicone film is further formed, when the CVD oxide film, the nitride film and the buffer oxide film that remain in the first active region side are etched, the poly-silicone film is removed.
